(19) United States
(12) Patent Application Publication
(10) Pub. No.: US 2020/0272791 A1
(43) Pub. Date: Aug. 27, 2020

(54) SYSTEMS AND METHODS FOR AUTOMATED CONVERSATIONS WITH A TRANSACTIONAL ASSISTANT

(71) Applicant: Conversica, Inc., Foster City, CA (US)

(72) Inventors: Siddhartha Reddy Jonnalagadda, Bothell, WA (US); Macgregor S. Gainor, Bellingham, WA (US); Connor Mack Gouge, Seattle, WA (US); Patrick D. Griffin, Bellingham, WA (US); Alexander Eliseev, Foster City, CA (US); Kerri Louise Rapes, Santiago (CL); Ivania Donoso Guzman, Foster City, CA (US); Andres Collao, Foster City, CA (US); Emmanuel Faddoul, Foster City, CA (US); Ernesto Trujillo, Foster City, CA (US); Oscar Oteiza, Foster City, CA (US); David Manriquez, Foster City, CA (US); Heilein Izaguirre, Foster City, CA (US); Will Kempff Beeler, Seattle, WA (US)

(21) Appl. No.: 16/799,698

(22) Filed: Feb. 24, 2020

Related U.S. Application Data
(60) Provisional application No. 62/810,923, filed on Feb. 26, 2019.

(51) Int. Cl. G06F 40/30; G06N 20/00; G06N 5/04; G06Q 10/06; G06F 30/10; G06F 40/295; G06F 40/242; G06F 40/205

(52) U.S. Cl. CPC G06F 40/30; G06N 20/00; G06N 5/04; G06Q 10/0637; G06F 40/205; G06F 30/10; G06F 40/295; G06F 40/242; G06Q 10/067

(57) ABSTRACT

Systems and methods for an automated conversation with a transactional assistant are provided. This conversation relies upon initially a set of exchanges being defined. Each exchange connected to every other exchange by bidirectional edge transitions. A response from the conversation target is received, and is processed for natural language understanding (NLU) generate intents and entities. After the NLU, a determination is made which bidirectional edge transition applies, as a function of the intent and the source exchange. Subsequently, the exchange may be transitioned to a new exchange based upon the determined bidirectional edge transition, and a response is formulated using natural language generation (NLG) for the new exchange.

### CROSS REFERENCE TO RELATED APPLICATION

This non-provisional application claims the benefit of provisional application No. 62/810,923, filed Feb. 26, 2019, same title, which application is incorporated herein in its entirety by this reference.

### BACKGROUND

The present invention relates to systems and methods for natural language processing and generation of more “human” sounding artificially generated conversations. Such natural language processing techniques may be employed in the context of machine learned conversation systems. These conversational AIs include, but are not limited to, message response generation, AI assistant performance, and other language processing, primarily in the context of the generation and management of a dynamic conversations. Such systems and methods provide a wide range of business people more efficient tools for outreach, knowledge delivery, automated task completion, and also improve computer functioning as it relates to processing documents for meaning. In turn, such system and methods enable more productive business conversations and other activities with a majority of tasks performed previously by human workers delegated to artificial intelligence assistants.

Artificial Intelligence (AI) is becoming ubiquitous across many technology platforms. AI enables enhanced productivity and enhanced functionality through “smarter” tools. Examples of AI tools include stock managers, chatbots, and voice activated search-based assistants such as Siri and Alexa. With the proliferation of these AI systems, however, come challenges for user engagement, quality assurance and oversight.

When it comes to user engagement, many people do not feel comfortable communicating with a machine outside of certain discrete situations. A computer system intended to converse with a human is typically considered limiting and frustrating. This has manifested in a deep anger many feel when dealing with automated phone systems, or spammed, non-personal emails.

These attitudes persist even when the computer system being conversed with is remarkably capable. For example, many personal assistants such as Siri and Alexa include very powerful natural language processing capabilities; however, the frustration when dealing with such systems, especially when they do not “get it” persists. Ideally an automated conversational system provides more organic sounding messages in order to reduce this natural frustration on behalf of the user. Indeed, in the perfect scenario, the user interfacing with the AI conversation system would be unaware that they are speaking with a machine rather than another human.

In order for a machine to sound more human or organic includes improvements in natural language processing and the generation of accurate, specific and contextual action to meaning rules.

It is therefore apparent that an urgent need exists for advancements in the natural language processing techniques used by AI conversation systems, including advanced transactional assistants that reduce burdens upon human operators tasked with intercepting conversations upon model deficiencies. Such transactional assistants may allow for non-sequential conversations to meet specific organizational objectives with less required human input.

### SUMMARY

To achieve the foregoing and in accordance with the present invention, systems and methods for natural language processing, automated conversations, and enhanced system functionality are provided. Such systems and methods allow for more effective AI operations through an advanced transactional assistant which reduces human input requirements due to the multi-dimensional conversation design.

In some embodiments, systems and methods are provided for an automated conversation with a transactional assistant. This conversation relies upon initially a set of exchanges being defined. Each exchange connected to every other exchange by bidirectional edge transitions. A response from the conversation target is received, and is processed for natural language understanding (NLU) generate intents and entities.

In some embodiments, intents are suggested by a human in the loop, or are modeled by supervised learning with deep learning, sentence similarity with at least one of term frequency-inverse document frequency, word embedding similarity, Siamese networks and sentence encodings, or pattern or exact matches. Entities are extracted by dictionary matches, recurrent neural networks, or regular expressions.

After the NLU, a determination is made which bidirectional edge transition applies, as a function of the intent and the source exchange. This determination may be made using deterministic approaches (e.g., Boolean rules on the intents and entities), offline policy learning using historical and audit data, or via reinforcement learning algorithms including multi-armed bandit problems.

Subsequently, the exchange may be transitioned to a new exchange based upon the determined bidirectional edge transition, and a response is formulated using natural language generation (NLG) for the new exchange. The natural language generation leverages phrase selection, including automated phasing and then curation by a human in the loop. Alternatively, phrase selection may be by sequence to sequence networks and transformer networks to augment the phrases, reinforcement learning algorithms, or unscripted messaging using mimic rephrase.

In some embodiments, it may also be desired to allow for new feature development for the transactional assistant. The feature development includes defining a business requirement for the feature, creating a technical design for it, and generating an optimal training desk responsive to the technical design using user experience design principles and A/B testing. Data from the training desk can then be collected and aggregated until a sufficient volume of relevant data has been accumulated. This is then used to generate a model for the feature, which is then deployed.

Lastly, the conversation with the transactional assistant may be customized by a customer. This includes collecting human in the loop responses for entities, intents, transaction actions, and replies as a set of annotations. These annotations are then intelligently queried via an annotation microservice, the results of which may be employed to automatically build out the NLU model, an inference engine (IE) model (for exchange transition modeling), and the NLG model. The newly built models) may then be automatically deployed, along with attendant notifications/alerts.

Note that the various features of the present invention described above may be practiced alone or in combination. These and other features of the present invention will be described in more detail below in the detailed description of the invention and in conjunction with the following figures.

### BRIEF DESCRIPTION OF THE DRAWINGS

In order that the present invention may be more clearly ascertained, some embodiments will now be described, by way of example, with reference to the accompanying drawings, in which:

FIG. 1 is an example logical diagram of a system for generation and implementation of messaging conversations, in accordance with some embodiment;

FIG. 2 is an example logical diagram of a dynamic messaging server, in accordance with some embodiment;

FIG. 3 is an example logical diagram of a user interface within the dynamic messaging server, in accordance with some embodiment;

FIG. 4 is an example logical diagram of a message generator within the dynamic messaging server, in accordance with some embodiment;

FIG. 5A is an example logical diagram of a message response system within the dynamic messaging server, in accordance with some embodiment;

FIG. 5B is an example logical diagram of the transactional assistant, in accordance with some embodiment;

FIG. 5C is an example logical diagram of a classifier, in accordance with some embodiment;

FIG. 5D is an example logical diagram of a delivery handler, in accordance with some embodiment;

FIG. 6 is an example flow diagram for a dynamic message conversation, in accordance with some embodiment;

FIG. 7 is an example flow diagram for the process of on-boarding a business actor, in accordance with some embodiment;

FIG. 8 is an example flow diagram for the process of building a business activity such as conversation, in accordance with some embodiment;

FIG. 9 is an example flow diagram for the process of generating message templates, in accordance with some embodiment;

FIG. 10 is an example flow diagram for the process of implementing the conversation, in accordance with some embodiment;

FIG. 11 is an example flow diagram for the process of preparing and sending the outgoing message, in accordance with some embodiment;

FIG. 12 is an example flow diagram for the process of processing received responses, in accordance with some embodiment;

FIG. 13 is an example flow diagram for the process of document cleaning, in accordance with some embodiment;

FIG. 14 is an example flow diagram for transactional assistant processing, in accordance with some embodiment;

FIG. 15 is an example flow diagram for natural language generation, in accordance with some embodiment;

FIG. 16 is an example flow diagram for feature training, in accordance with some embodiment; and

FIGS. 17A and 17B are example illustrations of a computer system capable of embodying the current invention.

### DETAILED DESCRIPTION

The present invention will now be described in detail with reference to several embodiments thereof as illustrated in the accompanying drawings. In the following description, numerous specific details are set forth in order to provide a thorough understanding of embodiments of the present invention. It will be apparent, however, to one skilled in the art, that embodiments may be practiced without some or all of these specific details. In other instances, well known process steps and/or structures have not been described in detail in order to not unnecessarily obscure the present invention. The features and advantages of embodiments may be better understood with reference to the drawings and discussions that follow.

Aspects, features and advantages of exemplary embodiments of the present invention will become better understood with regard to the following description in connection with the accompanying drawing(s). It should be apparent to those skilled in the art that the described embodiments of the present invention provided herein are illustrative only and not limiting, having been presented by way of example only. All features disclosed in this description may be replaced by alternative features serving the same or similar purpose, unless expressly stated otherwise. Therefore, numerous other embodiments of the modifications thereof are contemplated as falling within the scope of the present invention as defined herein and equivalents thereto. Hence, use of absolute and/or sequential terms, such as, for example, “will,” “will not,” “shall,” “shall not,” “must,” “must not,” “first,” “initially,” “next,” “subsequently,” “before,” “after,” “lastly,” and “finally,” are not meant to limit the scope of the present invention as the embodiments disclosed herein are merely exemplary.

The present invention relates to enhancements to traditional natural language processing techniques and subsequent actions taken by an automated system. While such systems and methods may be utilized with any AI system, such natural language processing particularly excel in AI systems relating to the generation of automated messaging for business conversations such as marketing and other sales functions. While the following disclosure is applicable for other combinations, we will focus upon natural language processing in AI marketing systems as an example, to demonstrate the context within which the enhanced natural language processing excels.

The following description of some embodiments will be provided in relation to numerous subsections. The use of subsections, with headings, is intended to provide greater clarity and structure to the present invention. In no way are the subsections intended to limit or constrain the disclosure contained therein. Thus, disclosures in any one section are intended to apply to all other sections, as is applicable.

The following systems and methods are for improvements in natural language processing and actions taken in response to such message exchanges, within conversation systems, and for employment of domain specific assistant systems that leverage these enhanced natural language processing techniques. The goal of the message conversations is to enable a logical dialog exchange with a recipient, where the recipient is not necessarily aware that they are communicating with an automated machine as opposed to a human user. This may be most efficiently performed via a written dialog, such as email, text messaging, chat, etc. However, given the advancement in audio and video processing, it may be entirely possible to have the dialog include audio or video components as well.

In order to effectuate such an exchange, an AI system is employed within an AI platform within the messaging system to process the responses and generate conclusions regarding the exchange. These conclusions include calculating the context of a document, intents, entities, sentiment and confidence for the conclusions. Human operators, through a “training desk” interface, cooperate with the AI to ensure as seamless an experience as possible, even when the AI system is not confident or unable to properly decipher a message, and through message annotation processes. The natural language techniques disclosed herein assist in making the outputs of the AI conversation system more effective, and more ‘human sounding’, which may be preferred by the recipient/target of the conversation.

### I. Dynamic Messaging Systems with Enhanced Natural Language Processing

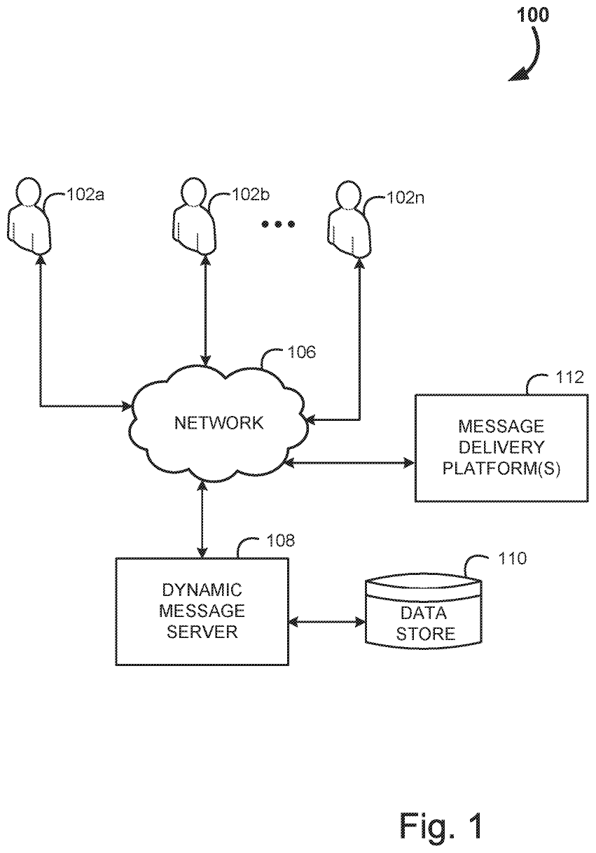

To facilitate the discussion, FIG. 1 is an example logical diagram of a system for generating and implementing messaging conversations, shown generally at 100. In this example block diagram, several users 102a-n are illustrated engaging a dynamic messaging system 108 via a network 106. Note that messaging conversations may be uniquely customized by each user 102a-n in some embodiments. In alternate embodiments, users may be part of collaborative sales departments (or other collaborative group) and may all have common access to the messaging conversations. The users 102a-n may access the network from any number of suitable devices, such as laptop and desktop computers, work stations, mobile devices, media centers, etc.

The network 106 most typically includes the internet but may also include other networks such as a corporate WAN, cellular network, corporate local area network, or combination thereof, for example. The messaging server 108 may distribute the generated messages to the various message delivery platforms 112 for delivery to the individual recipients. The message delivery platforms 112 may include any suitable messaging platform. Much of the present disclosure will focus on email messaging, and in such embodiments the message delivery platforms 112 may include email servers (Gmail, Yahoo, Outlook, etc.). However, it should be realized that the presently disclosed systems for messaging are not necessarily limited to email messaging. Indeed, any messaging type is possible under some embodiments of the present messaging system. Thus, the message delivery platforms 112 could easily include a social network interface, instant messaging system, text messaging (SMS) platforms, or even audio or video telecommunications systems.

One or more data sources 110 may be available to the messaging server 108 to provide user specific information, message template data, knowledge sets, intents, and target information. These data sources may be internal sources for the system's utilization or may include external third-party data sources (such as business information belonging to a customer for whom the conversation is being generated). These information types will be described in greater detail below. This information may be leveraged, in some embodiments, to generate a profile regarding the conversation target. A profile for the target may be particularly useful in a sales setting where differing approaches may yield dramatically divergent outcomes. For example, if it is known that the target is a certain age, with young children, and with an income of $75,000 per year, a conversation assistant for a car dealership will avoid presenting the target with information about luxury sports cars, and instead focus on sedans, SUVs and minivans within a budget the target is likely able to afford. By engaging the target with information relevant to them, and sympathetic to their preferences, the goals of any given conversation are more likely to be met. The external data sources typically relied upon to build out a target profile may include, but are not limited to, credit applications, CRM data sources, public records data sets, loyalty programs, social media analytics, and other “pay to play” data sets, for example.

The other major benefit of a profile for the target is that data that the system “should know” may be incorporated into the conversation to further personalize the message exchange. Information the system “should know” is data that is evident trough the exchange, or the target would expect the AI system would know. Much of the profile data may be public, but a conversation target would feel strange (or even violated) to know that the other party they are communicating with has such a full set of information regarding them. For example, a consumer doesn't typically assume a retailer knows how they voted in the last election, but through an AI conversational system with access to third party data sets, this kind of information may indeed be known. Bringing up such knowledge in a conversation exchange would strike the target as strange, at a minimum, and may actually interfere with achieving the conversation objectives. In contrast, offered information, or information the target assumes the other party has access to, can be incorporated into the conversation in a manner that personalizes the exchange, and makes the conversation more organic sounding. For example if the target mentions having children, and is engaging an AI system deployed for an automotive dealer, a very natural message exchange could include “You mentioned wanting more information on the Highlander SUV. We have a number in stock, and one of our sales reps would love to show you one and go for a test drive. Plus they are great for families. I'm sure your kids would love this car.”

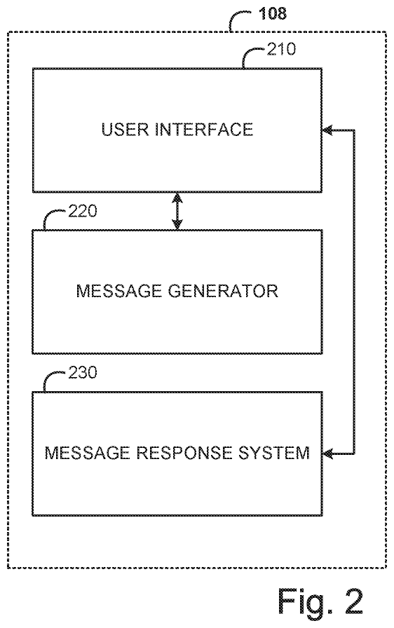

Moving on, FIG. 2 provides a more detailed view of the dynamic messaging server 108, in accordance with some embodiment. The server is comprised of three main logical subsystems: a user interface 210, a message generator 220, and a message response system 230. The user interface 210 may be utilized to access the message generator 220 and the message response system 230 to set up messaging conversations and manage those conversations throughout their life cycle. At a minimum, the user interface 210 includes APIs to allow a user's device to access these subsystems. Alternatively, the user interface 210 may include web accessible messaging creation and management tools.

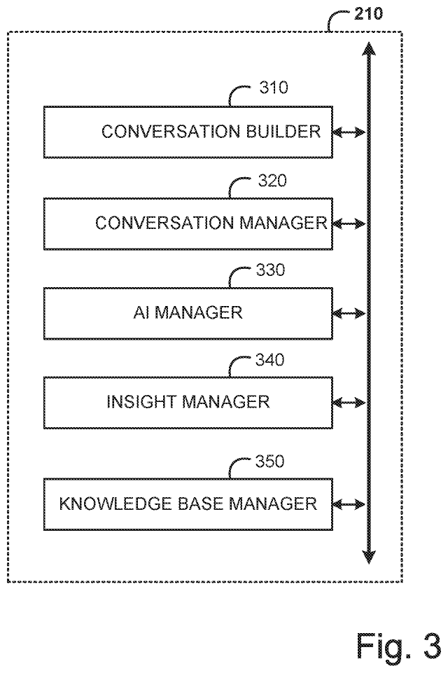

FIG. 3 provides a more detailed illustration of the user interface 210. The user interface 210 includes a series of modules to enable the previously mentioned functions to be carried out in the message generator 220 and the message response system 230. These modules include a conversation builder 310, a conversation manager 320 an AI manager 330, an intent manager 340, and a knowledge base manager 350.

The conversation builder 310 allows the user to define a conversation, and input message templates for each series/exchange within the conversation. A knowledge set and target data may be associated with the conversation to allow the system to automatically effectuate the conversation once built. Target data includes all the information collected on the intended recipients, and the knowledge set includes a database from which the AI can infer context and perform classifications on the responses received from the recipients.

The conversation manager 320 provides activity information, status, and logs of the conversation once it has been implemented. This allows the user 102a to keep track of the conversation's progress, success and allows the user to manually intercede if required. The conversation may likewise be edited or otherwise altered using the conversation manager 320.

The AI manager 330 allows the user to access the training of the artificial intelligence which analyzes responses received from a recipient. One purpose of the given systems and methods is to allow very high throughput of message exchanges with the recipient with relatively minimal user input. To perform this correctly, natural language processing by the AI is required, and the AI (or multiple AI models) must be correctly trained to make the appropriate inferences and classifications of the response message. The user may leverage the AI manager 330 to review documents the AI has processed and has made classifications for.

In some embodiments, the training of the AI system may be enabled by, or supplemented with, conventional CRM data. The existing CRM information that a business has compiled over years of operation is incredibly rich in detail, and specific to the business. As such, by leveraging this existing data set the AI models may be trained in a manner that is incredibly specific and valuable to the business. CRM data may be particularly useful when used to augment traditional training sets, and input from the training desk. Additionally, social media exchanges may likewise be useful as a training source for the AI models. For example, a business often engages directly with customers on social media, leading to conversations back and forth that are again, specific and accurate to the business. As such this data may also be beneficial as a source of training material.

The intent manager 340 allows the user to manage intents. As previously discussed, intents are a collection of categories used to answer some question about a document. For example, a question for the document could include “is the lead looking to purchase a car in the next month?” Answering this question can have direct and significant importance to a car dealership. Certain categories that the AI system generates may be relevant toward the determination of this question. These categories are the ‘intent’ to the question and may be edited or newly created via the intent manager 340. As will be discussed in greater detail below, the generation of questions and associated intents may be facilitated by leveraging historical data via a recommendation engine.

In a similar manner, the knowledge base manager 350 enables the management of knowledge sets by the user. As discussed, a knowledge set is a set of tokens with their associated category weights used by an aspect (AI algorithm) during classification. For example, a category may include “continue contact?”, and associated knowledge set tokens could include statements such as “stop”, “do no contact”, “please respond” and the like.

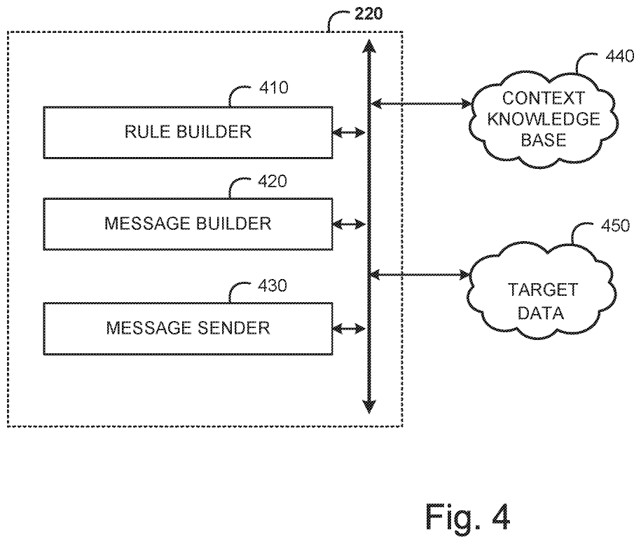

Moving on to FIG. 4, an example logical diagram of the message generator 220 is provided. The message generator 220 utilizes context knowledge 440 and target data 450 to generate the initial message. The message generator 220 includes a rule builder 410 which allows the user to define rules for the messages. A rule creation interface which allows users to define a variable to check in a situation and then alter the data in a specific way. For example, when receiving the scores from the AI, if the intent is Interpretation and the chosen category is ‘good’, then have the Continue Messaging intent return ‘continue’.

The rule builder 410 may provide possible phrases for the message based upon available target data. The message builder 420 incorporates those possible phrases into a message template, where variables are designated, to generate the outgoing message. Multiple selection approaches and algorithms may be used to select specific phrases from a large phrase library of semantically similar phrases for inclusion into the message template. For example, specific phrases may be assigned category rankings related to various dimensions such as “formal vs. informal, education level, friendly tone vs. unfriendly tone, and other dimensions,” Additional category rankings for individual phrases may also be dynamically assigned based upon operational feedback in achieving conversational objectives so that more “successful” phrases may be more likely to be included in a particular message template. Phrase package selection will be discussed in further detail below. The selected phrases incorporated into the template message is provided to the message sender 430 which formats the outgoing message and provides it to the messaging platforms for delivery to the appropriate recipient.

Feedback may be collected from the conversational exchanges, in many embodiments. For example if the goal of a given message exchange is to set up a meeting, and the target agrees to said meeting, this may be counted as successful feedback. However, it may also be desirable to collect feedback from external systems, such as transaction logs in a point of sales system, or through records in a CRM system.

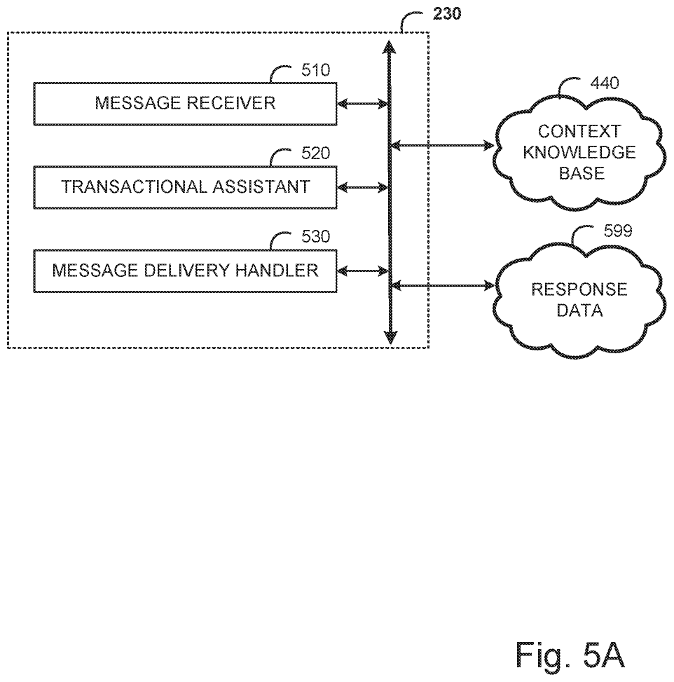

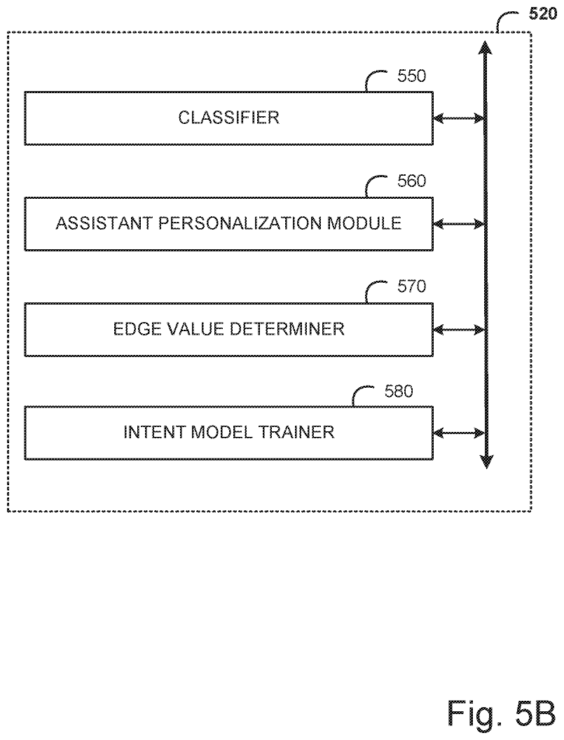

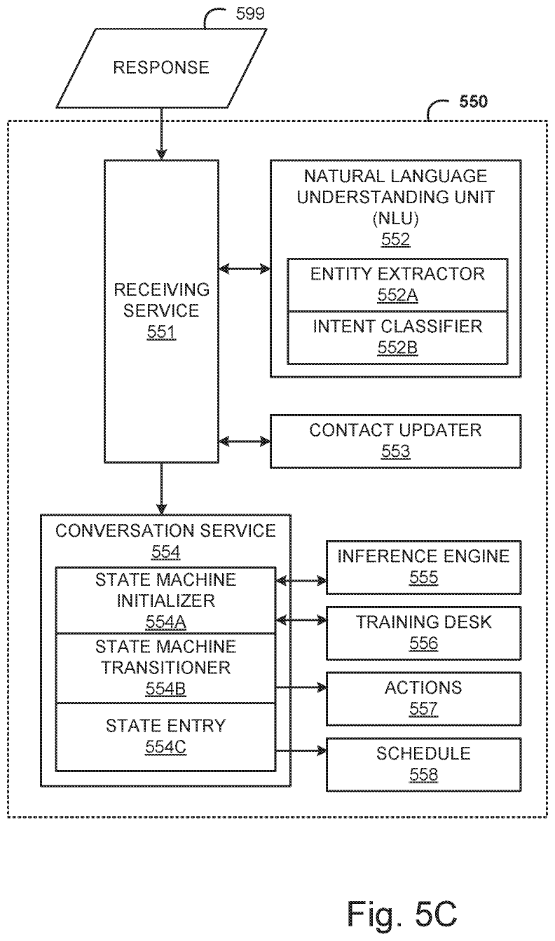

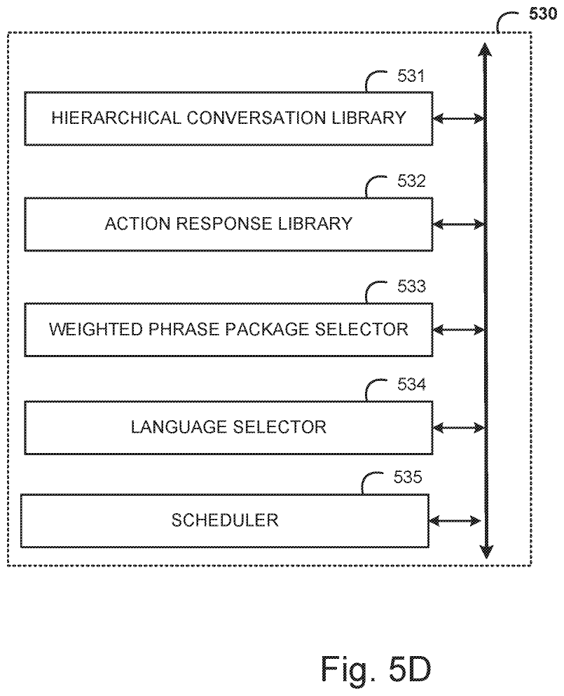

FIG. 5A is an example logical diagram of the message response system 230. In this example system, the context knowledge base 440 is utilized in combination with response data 599 received from the person being messaged (the target or recipient). The message receiver 510 receives the response data 599 and provides it to the transactional assistant 520 for processing. This processing may include a suite of tools that enable classification of the messages using machine learned models, and based on the classifications, target objectives may be updated and the subsequent actions to be taken may be determined. A scheduler and message delivery handler 530 may coordinate the execution of these determined activities, and interface with third party email systems to deliver response messages.

The message delivery handler 530 enables not only the delivery of the generated responses, but also may effectuate the additional actions beyond mere response delivery (when desired). The message delivery handler 530 may include phrase selections (if not completed by the transactional assistant 520), contextualizing the response by historical activity, through language selection, and execute additional actions like status updates, appointment setting, and the like.

As noted before, all machine learning NLP processes are exceptionally complicated and subject to frequent failure. Even for very well trained models, jargon and language usage develops over time, and differs between different contextual situation, thereby requiring continual improvement of the NLP systems to remain relevant and of acceptable accuracy. This results in the frequent need for human intervention in a conversation (a “human in the loop” or “HitL”). The major purpose of the transactional assistant 520 is the ability to have dynamic conversations with a variety of exchange states that may transition between all other exchange states (as opposed to serialized conversation flows). By allowing for these multi-nodal conversations, the system can be more responsive to the incoming messages; and through continual feature training and deployment, can significantly reduce the burden/need for human operators in the process.

Many of the aforementioned system components benefit from collecting detailed information from existing external systems within an organization (or more globally). A scraper (not illustrated) enables the collection of these data streams to allow these systems to operate more effectively.

Turning to FIG. 5B, details of the transactional assistant 520 are provided in greater detail. Initially messages are that have been cleansed and pre-processed are subjected to natural language understanding (NLU) via machine learning neural network classifiers 550. Prior to any processing, the response 599 may be subject to any number of preprocessing activities, such as parsing, normalization and error corrections. For example, a parser (not illustrated) could consume the raw message and splits it into multiple portions, including differentiating between the salutation, reply, close, signature and other message components, for example. Likewise, a tokenizer may break the response into individual sentences and n-grams.

The output of this classification system includes intents and entity information. The response 599 is received by a receiving service 551, which may correspond with natural language understanding (NLU) unit 552. The NLU unit 552 includes two subcomponents, an entity extractor 552A and an intent classifier 552B. Both the entity extractor 552A and the intent extractor 552B utilize a combination of rules and machine learned models to identify entities and intentions, respectively, found in the response. Particularly, an end-end neural approach is used where multiple components are stacked within a single deep neural network. These components include an encoder, a reasoner and a decoder. This differs from traditional AI systems which usually use a single speech recognition model, word-level analytics, syntactical parsing, information extractors, application reasoning, utterance planning, syntactic realization, text generation and speech synthesis.

In the present neural encoder, the encoding portion represents the natural language inputs and knowledge as dense, high-dimensional vectors using embeddings, such as dependency-based word embedding and bilingual word embeddings, as well as word representations by semi-supervised learning, semantic representations using conventional neural networks for web search, and parsing of natural scenes and natural language using recursive neural networks.

The reasoner portion of the neural encoder classifies the individual instance or sequence of these resulting vectors into a different instance or sequence typically using supervised approaches such as convolutional networks (for sentence classification) and recurrent networks (for the language model) and/or unsupervised approaches such as generative adversarial networks and auto-encoders (for reducing the dimensionality of data within the neural networks).

Lastly, the decoders of the neural encoder converts the vector outputs of the reasoner functions into symbolic space from which encoders originally created the vector representations. In some embodiments the neural encoder may include three functional tasks: natural language understanding (including intent classification and named entity recognition), inference (which includes learning policies and implementation of these policies appropriate to the objective of the conversation system using reinforcing learning or a precomputed policy), and natural language generation (by taking into account an action/decision made based upon the intent and incorporating AI models for emotion and knowledge sets).

The neural encoder accomplishes these tasks by automatically deriving a list of intents that that describe a conversational domain such that for every response from the user, the conversational AI system is able to predict how likely the user wanted to express intent, and the AI agent's policy can be evaluated using the intents and corresponding entities in the response to determine the agent's action. This derivation of intents uses data obtained from many enterprise assistant conversation flows. Each conversation flow was designed based on the reason for communication, the targeted goal and objectives, and key verbiage from the customer to personalize the outreach. These conversation flows are subdivided by their business functions (e.g., sales assistants selling automobiles, technology products, financial products and other products, service assistants, finance assistants, customer success assistants, collections assistants, recruiting assistants, etc.).

The response 599, as discussed, is natural language text or speech from the human to AI. The neural encoding network uses word embedding models first to encode each token into a vector in a dense high-dimensional vector space. The network is extended to also represent sentences and paragraphs of the response in the vector space. These encodings are passed to a set of four models: named entities extraction, a recurrent neural network (RNN) classifying intents at paragraph-level, and a different recurrent neural network which uses the outputs of neural encoder and classifies the individual sentences into intents. The sentence-level intents and paragraph-level intents share the taxonomy but have a distinct set of labels. Fourth, a K-nearest neighbor algorithm is used on sentence representation to group semantically identical (or similar) sentences. When a cluster of semantically similar groups is big enough, the corresponding RNN model is trained via a trainer for the groups and creates a new sentence intent RNN network and add it the set of sentence intents if bias and variance are low.

Entities may include people, objects, locations, phone numbers, email addresses, dates, businesses and the like. Intents, on the other hand, are coded based upon business needs, or may be identified automatically through training or through interaction with a training desk. Particular intents of interest for a business conversation could include, for example, satisfied, disqualified, no further action and further action, in some embodiments. These intents may correspond to situations where the goals for a conversation target have been met (satisfied intent), where such goals are unable to be met (disqualified), where the goal is in progress without need for additional messaging (no further action), and where the goal is in process but requires additional information or messaging to be fully resolved (further action).

The receiving service 551 also may couple to a contact updater 553 which may update entity information, but operates independently of any conversation state transition. Contact updates are a side effect of receiving a response, and as such may be transition callback processes.

After the receiving service 551 completes its analysis of the received response, a conversation service module 554 may continue the classification. The conversation service module 554 may consist of a state machine initializer 554A that starts at an initial state and uses an inference engine 555 to determine which state to transition to. Particularly, the outputs of each of the models represent the state of the environment is shared with the agent in a reinforcement learning setting. The agent applies a policy to optimize a reward and decide upon an action. If the action is not inferred with a suitable threshold of confidence, an annotation platform requests annotation of sentence intents using active learning. In circumstances where the inference engine 555 is unsure of what state to transition to (due to a model confidence below an acceptable threshold), a training desk 556 may alternatively be employed. A state machine transitioner 554B updates the state from the initial state to an end state for the response. Actions 557 may result from this state transition. Actions may include webhooks, accessing external systems for appointment setting, or may include status updates. Once an action is done, it typically is a permanent event. A state entry 554C component may populate scheduling rows on a state entry once associated with a schedule 558 received from the scheduler 540.

Returning to FIG. 5B, in addition to classification, the transactional assistant may be assigned a “personality”, and may be personalized by a specific client. All personalization (including custom model generation or training) may be effectuated by an assistant personalization module 560.

As noted before, the transactional assistant 520 enables not only serialized conversations, but conversations that include a series of exchanges, which are represented as a set of states. An edge value determiner 570 may determine an edge value for a given state based upon the starting exchange position (initial state) and the results of the NLU activity (classification, intents and entities). This edge determination may be deterministic, or may be decided based upon multi-armed bandit or offline policy learning.

The inclusion of multiple exchanges in the transactional assistant, each capable of transitioning to other exchanges by multi-armed bandit, deterministic, or other models, necessitates that the system includes a highly automated and scalable self-learning ability. To this end, an intent model trainer 580 exists to undergo identification of a feature, defining a business requirement and collection of training data for the feature for automated model generation and deployment.

Moving on, FIG. 5D provides an example delivery handler 530, which is presented in greater detail. The message delivery handler 530 receives output from the earlier components and performs its own processing to arrive at the final outgoing message. The message delivery handler 530 may include a hierarchical conversation library 531 for storing all the conversation components for building a coherent message. The hierarchical conversation library 531 may be a large curated library, organized and utilizing multiple inheritance along a number of axes: organizational levels, access-levels (rep->group->customer->public). The hierarchical conversation library 531 leverages sophisticated library management mechanisms, involving a rating system based on achievement of specific conversation objectives, gamification via contribution rewards, and easy searching of conversation libraries based on a clear taxonomy of conversations and conversation trees.

In addition to merely responding to a message with a response, the message delivery handler 530 may also include a set of actions that may be undertaken linked to specific triggers, these actions and associations to triggering events may be stored in an action response library 532. For example, a trigger may include “Please send me the brochure.” This trigger may be linked to the action of attaching a brochure document to the response message, which may be actionable via a webhook or the like. The system may choose attachment materials from a defined library (SalesForce repository, etc.), driven by insights gained from parsing and classifying the previous response, or other knowledge obtained about the target, client, and conversation. Other actions could include initiating a purchase (order a pizza for delivery for example) or pre-starting an ancillary process with data known about the target (kick of an application for a car loan, with name, etc. already pre-filled in for example). Another action that is considered is the automated setting and confirmation of appointments.

The message delivery handler 530 may have a weighted phrase package selector 533 that incorporates phrase packages into a generated message based upon their common usage together, or by some other metric. Lastly, the message delivery handler 530 may operate to select which language to communicate using a language selector 534. Rather than perform classifications using full training sets for each language, as is the traditional mechanism, the systems leverage dictionaries for all supported languages, and translations to reduce the needed level of training sets. In such systems, a primary language is selected, and a full training set is used to build a model for the classification using this language. Smaller training sets for the additional languages may be added into the machine learned model. These smaller sets may be less than half the size of a full training set, or even an order of magnitude smaller. When a response is received, it may be translated into all the supported languages, and this concatenation of the response may be processed for classification. The flip side of this analysis is the ability to alter the language in which new messages are generated. For example, if the system detects that a response is in French, the classification of the response may be performed in the above-mentioned manner, and similarly any additional messaging with this contact may be performed in French.

Determination of which language to use is easiest if the entire exchange is performed in a particular language. The system may default to this language for all future conversation. Likewise, an explicit request to converse in a particular language may be used to determine which language a conversation takes place in. However, when a message is not requesting a preferred language, and has multiple language elements, the system may query the user on a preferred language and conduct all future messaging using the preferred language.

A scheduler 535 used rules for messaging timing and learned behaviors in order to output the message at an appropriate time. For example, when emailing, humans generally have a latency in responding that varies from a few dozen minutes to a day or more. Having a message response sent out too quickly seems artificial. A response exceeding a couple of days, depending upon the context, may cause frustration, irrelevance, or may not be remembered by the other party. As such, the scheduler 535 aims to respond in a more ‘human’ timeframe and is designed to maximize a given conversation objective.

### II. Methods

Now that the systems for dynamic messaging and natural language processing techniques have been broadly described, attention will be turned to processes employed to perform transactional assistant driven conversations.

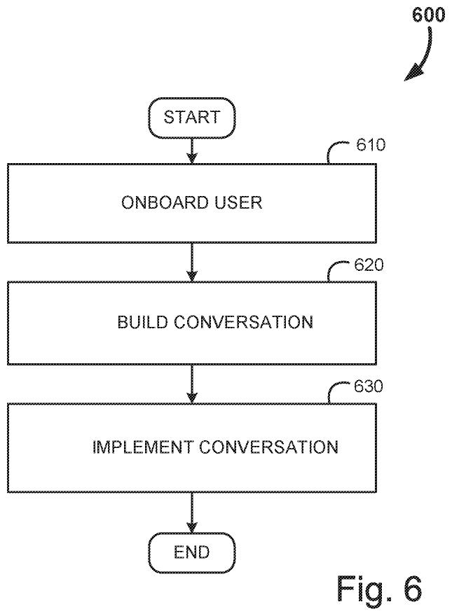

In FIG. 6 an example flow diagram for a dynamic message conversation is provided, shown generally at 600. The process can be broadly broken down into three portions: the on-boarding of a user (at 610), conversation generation (at 620) and conversation implementation (at 630). The following figures and associated disclosure will delve deeper into the specifics of these given process steps.

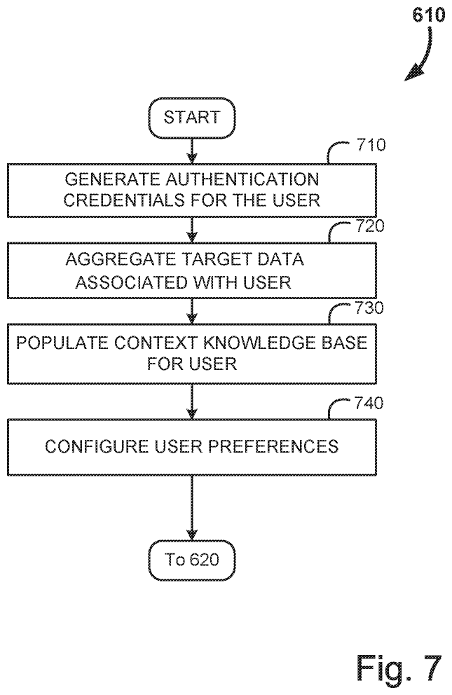

FIG. 7, for example, provides a more detailed look into the on-boarding process, shown generally at 610. Initially a user is provided (or generates) a set of authentication credentials (at 710). This enables subsequent authentication of the user by any known methods of authentication. This may include username and password combinations, biometric identification, device credentials, etc.

Next, the target data associated with the user is imported, or otherwise aggregated, to provide the system with a target database for message generation (at 720). Likewise, context knowledge data may be populated as it pertains to the user (at 730). Often there are general knowledge data sets that can be automatically associated with a new user; however, it is sometimes desirable to have knowledge sets that are unique to the user's conversation that wouldn't be commonly applied. These more specialized knowledge sets may be imported or added by the user directly.

Lastly, the user is able to configure their preferences and settings (at 740). This may be as simple as selecting dashboard layouts, to configuring confidence thresholds required before alerting the user for manual intervention.

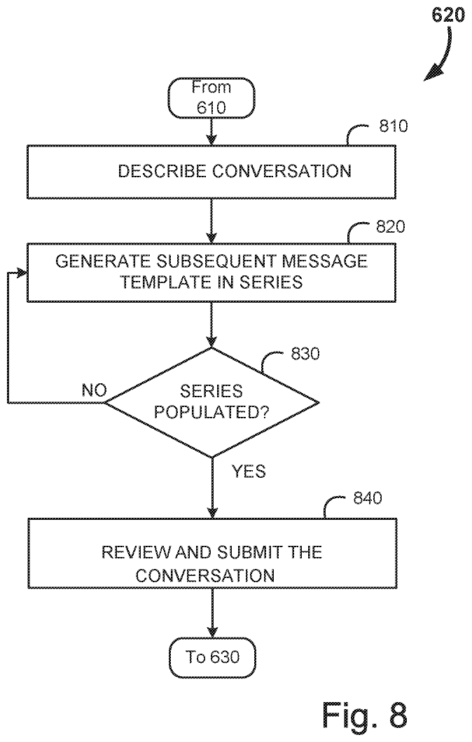

Moving on, FIG. 8 is the example flow diagram for the process of building a conversation, shown generally at 620. The user initiates the new conversation by first describing it (at 810). Conversation description includes providing a conversation name, description, industry selection, and service type. The industry selection and service type may be utilized to ensure the proper knowledge sets are relied upon for the analysis of responses.

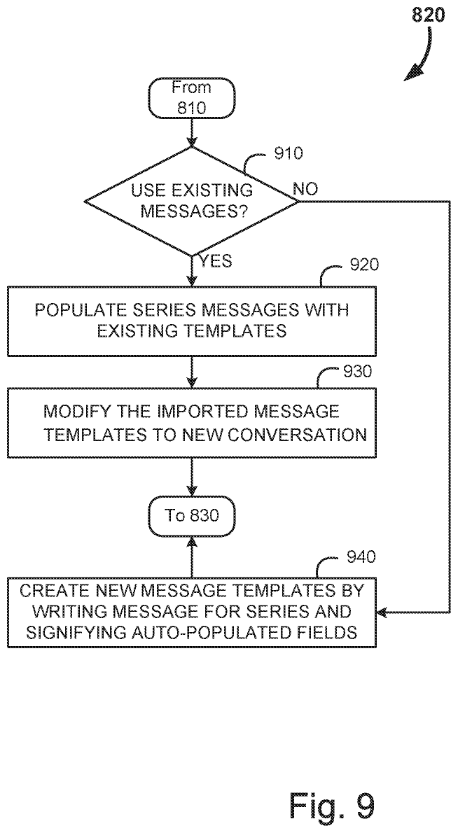

After the conversation is described, the message templates in the conversation are generated (at 820). If the exchanges in the conversation are populated (at 830), then the conversation is reviewed and submitted (at 840). Otherwise, the next message in the template is generated (at 820). FIG. 9 provides greater details of an example of this sub-process for generating message templates. Initially the user is queried if an existing conversation can be leveraged for templates, or whether a new template is desired (at 910).

If an existing conversation is used, the new message templates are generated by populating the templates with existing templates (at 920). The user is then afforded the opportunity to modify the message templates to better reflect the new conversation (at 930). Since the objectives of many conversations may be similar, the user will tend to generate a library of conversations and conversation fragments that may be reused, with or without modification, in some situations. Reusing conversations has time saving advantages, when it is possible.

However, if there is no suitable conversation to be leveraged, the user may opt to write the message templates from scratch using the a conversation editor (at 940). When a message template is generated, the bulk of the message is written by the user, and variables are imported for regions of the message that will vary based upon the target data. Successful messages are designed to elicit responses that are readily classified. Higher classification accuracy enables the system to operate longer without user interference, which increases conversation efficiency and user workload.

Messaging conversations can be broken down into individual objectives for each target. Designing conversation objectives allows for a smoother transition between messaging exchanges. Table 1 provides an example set of messaging objectives for an example sales conversation.

TABLE 1
Template Objectives

Objective
Verify Email Address
Obtain Phone Number
Introduce Sales Representative
Verify Rep Follow-Up

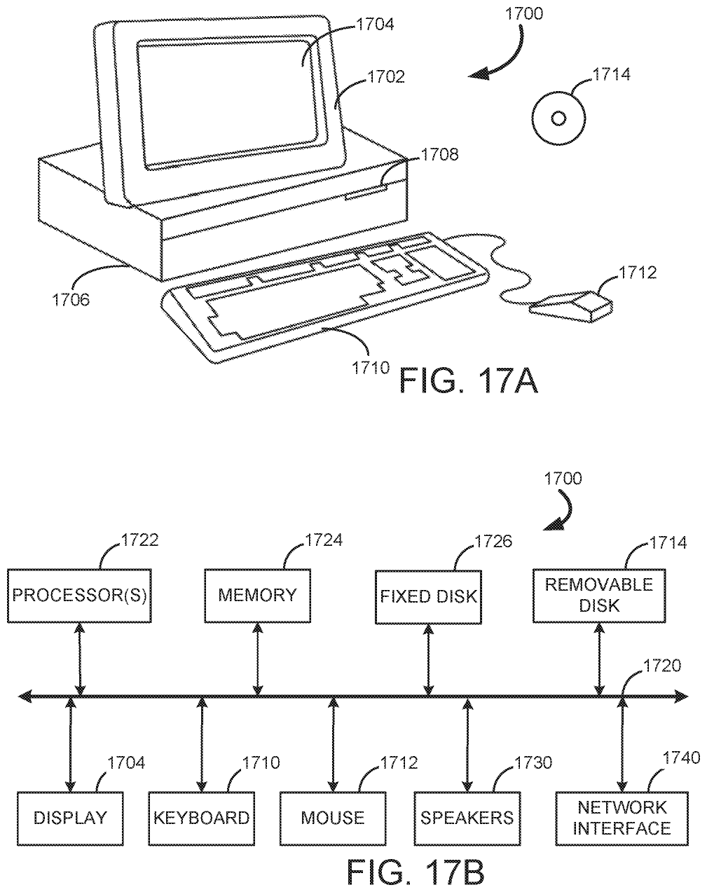

Likewise, conversations can have other arbitrary set of objectives as dictated by client preference, business function, business vertical, channel of communication and language. As previously noted, FIG. 17, for example, lists possible objectives for conversation exchanges in the example illustration 1700. Objective definition can track the state of every target. Inserting personalized objectives allows immediate question answering at any point in the lifecycle of a target. The state of the conversation objectives can be tracked individually as shown below in reference to Table 2.

TABLE 2
Objective tracking

| Target | Conversation | | | | |
|---|---|---|---|---|---|
| ID | ID | Objective | Type | Pending | Complete |
| 100 | 1 | Verify Email | Q | 1 | 1 |
| | | Address | | | |
| 100 | 1 | Obtain Phone | Q | 0 | 1 |
| | | Number | | | |
| 100 | 1 | Give Location | I | 1 | 0 |
| | | Details | | | |
| 100 | 1 | Verify Rep | Q | 0 | 0 |
| | | Follow-Up | | | |

Table 2 displays the state of an individual target assigned to conversation 1, as an example. With this design, the state of individual objectives depends on messages sent and responses received. Objectives can be used with an informational template to make an exchange transition seamless. Tracking a target's objective completion allows for improved definition of target's state, and alternative approaches to conversation message building. Conversation objectives are not immediately required for dynamic message building implementation but become beneficial soon after the start of a conversation to assist in determining when to transition from one exchange to another.

Dynamic message building design depends on ‘message building’ rules in order to compose an outbound document. A Rules child class is built to gather applicable phrase components for an outbound message. Applicable phrases depend on target variables and target state.

To recap, to build a message, possible phrases are gathered for each template component in a template iteration. In some embodiment, a single phrase can be chosen randomly from possible phrases for each template component. Alternatively, as noted before, phrases are gathered and ranked by “relevance”. Each phrase can be thought of as a rule with conditions that determine whether or not the rule can apply and an action describing the phrase's content.

Relevance is calculated based on the number of passing conditions that correlate with a target's state. A single phrase is selected from a pool of most relevant phrases for each message component. Chosen phrases are then imploded to obtain an outbound message. Logic can be universal or data specific as desired for individual message components.

Variable replacement can occur on a per phrase basis, or after a message is composed. Post message-building validation can be integrated into a message-building class. All rules interaction will be maintained with a messaging rules model and user interface.

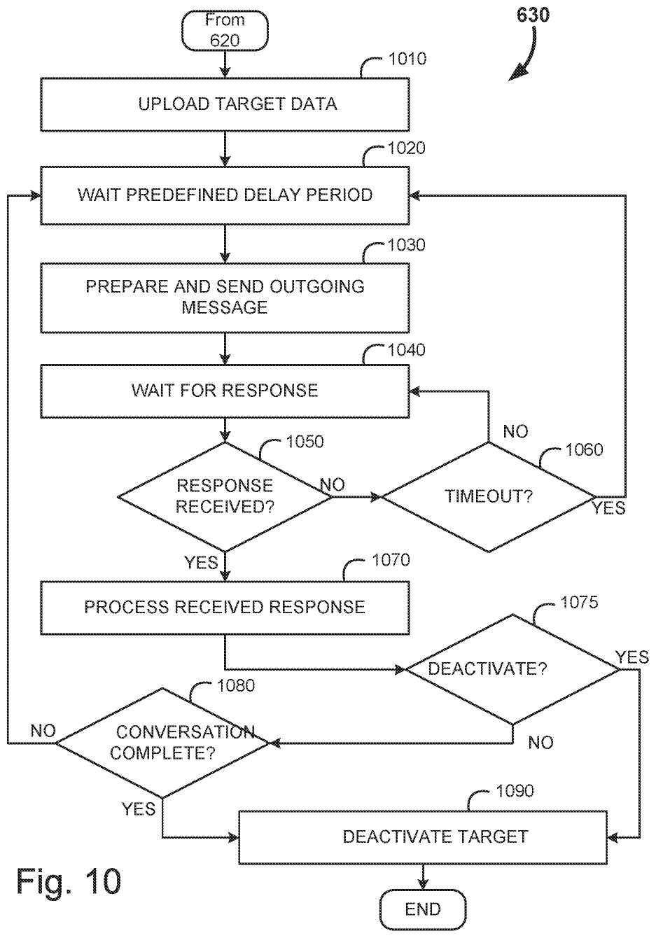

Once the conversation has been built out it is ready for implementation. FIG. 10 is an example flow diagram for the process of implementing the conversation, shown generally at 630. Here the lead (or target) data is uploaded (at 1010). Target data may include any number of data types, but commonly includes names, contact information, date of contact, item the target was interested in (in the context of a sales conversation), etc. Other data can include open comments that targets supplied to the target provider, any items the target may have to trade in, and the date the target came into the target provider's system. Often target data is specific to the industry, and individual users may have unique data that may be employed.

An appropriate delay period is allowed to elapse (at 1020) before the message is prepared and sent out (at 1030). The waiting period is important so that the target does not feel overly pressured, nor the user appears overly eager. Additionally, this delay more accurately mimics a human correspondence (rather than an instantaneous automated message). Additionally, as the system progresses and learns, the delay period may be optimized by a cadence optimizer to be ideally suited for the given message, objective, industry involved, and actor receiving the message.

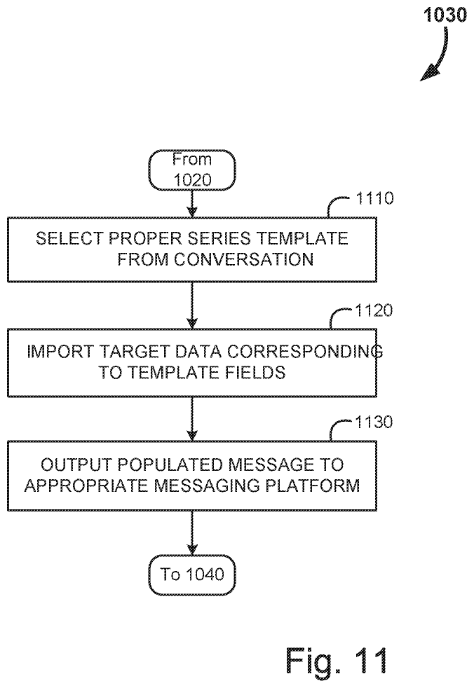

FIG. 11 provides a more detailed example of the message preparation and output. In this example flow diagram, the message within the series is selected based upon the source exchange and any NLU results via deterministic rules, or via models such as multi-armed bandit problem (at 1110). The initial message is generally deterministically selected based upon how the conversation is initiated (e.g., system reaching out to new customer, vs customer contacting the system, vs prior customer re-contact, etc.). Typically, if the recipient didn't respond as expected, or not at all, it may be desirous to have alternate message templates to address the target most effectively.

After the message template is selected, the target data is parsed through, and matches for the variable fields in the message templates are populated (at 1120). Variable filed population, as touched upon earlier, is a complex process that may employ personality matching, and weighting of phrases or other inputs by success rankings. These methods will also be described in greater detail when discussed in relation to variable field population in the context of response generation. Such processes may be equally applicable to this initial population of variable fields.

In addition, or alternate to, personality matching or phrase weighting, selection of wording in a response could, in some embodiments, include matching wording or style of the conversation target. People, in normal conversation, often mirror each other's speech patterns, mannerisms and diction. This is a natural process, and an AI system that similarly incorporates a degree of mimicry results in a more ‘humanlike’ exchange.

Additionally, messaging may be altered by the class of the audience (rather than information related to a specific target personality). For example, the system may address an enterprise customer differently than an individual consumer. Likewise, consumers of one type of good or service may be addressed in subtly different ways than other customers. Likewise, a customer service assistant may have a different tone than an HR assistant, etc.

The populated message is output to the communication channel appropriate messaging platform (at 1130), which as previously discussed typically includes an email service, but may also include SMS services, instant messages, social networks, audio networks using telephony or speakers and microphone, or video communication devices or networks or the like. In some embodiments, the contact receiving the messages may be asked if he has a preferred channel of communication. If so, the channel selected may be utilized for all future communication with the contact. In other embodiments, communication may occur across multiple different communication channels based upon historical efficacy and/or user preference. For example, in some particular situations a contact may indicate a preference for email communication. However, historically, in this example, it has been found that objectives are met more frequently when telephone messages are utilized. In this example, the system may be configured to initially use email messaging with the contact, and only if the contact becomes unresponsive is a phone call utilized to spur the conversation forward. In another embodiment, the system may randomize the channel employed with a given contact, and over time adapt to utilize the channel that is found to be most effective for the given contact.

Returning to FIG. 10, after the message has been output, the process waits for a response (at 1040). If a response is not received (at 1050) the process determines if the wait has been timed out (at 1060). Allowing a target to languish too long may result in missed opportunities; however, pestering the target too frequently may have an adverse impact on the relationship. As such, this timeout period may be user defined and will typically depend on the communication channel. Often the timeout period varies substantially, for example for email communication the timeout period could vary from a few days to a week or more. For real-time chat communication channel implementations, the timeout period could be measured in seconds, and for voice or video communication channel implementations, the timeout could be measured in fractions of a second to seconds. If there has not been a timeout event, then the system continues to wait for a response (at 1050). However, once sufficient time has passed without a response, it may be desirous to return to the delay period (at 1020) and send a follow-up message (at 1030). Often there will be available reminder templates designed for just such a circumstance.

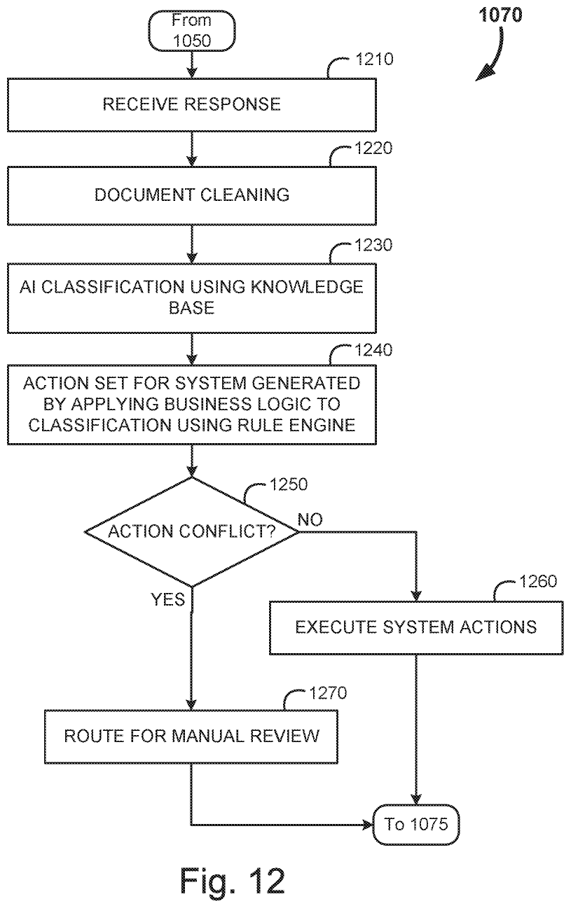

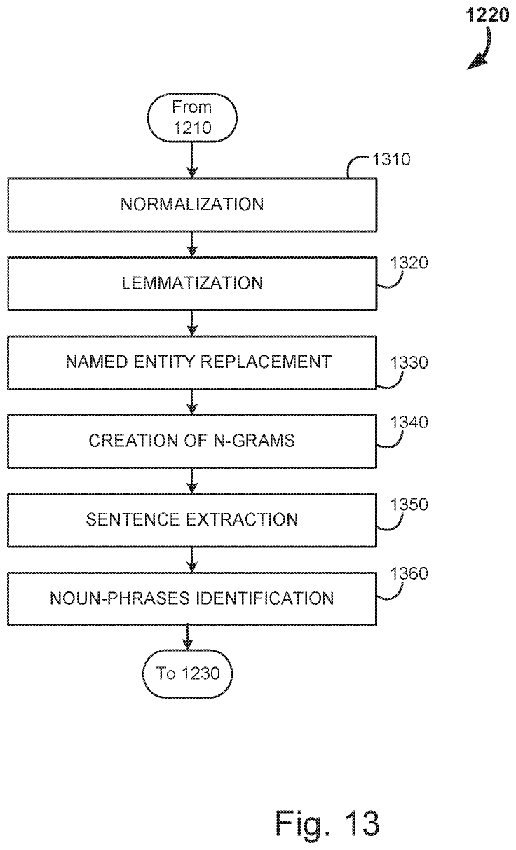

However, if a response is received, the process may continue with the response being processed (at 1070). This processing of the response is described in further detail in relation to FIG. 12. In this sub-process, the response is initially received (at 1210) and the document may be cleaned (at 1220). Document cleaning is described in greater detail in relation with FIG. 13. Upon document receipt, adapters may be utilized to extract information from the document for shepherding through the cleaning and classification pipelines. For example, for an email, adapters may exist for the subject and body of the response, often a number of elements need to be removed, including the original message, HTML encoding for HTML style responses, enforce UTF-8 encoding so as to get diacritics and other notation from other languages, and signatures so as to not confuse the AI. Only after all this removal process does the normalization process occur (at 1310) where characters and tokens are removed in order to reduce the complexity of the document without changing the intended classification.

After the normalization, documents are further processed through lemmatization (at 1320), name entity replacement (at 1330), the creation of n-grams (at 1340) sentence extraction (at 1350), noun-phrase identification (at 1360) and extraction of out-of-office features and/or other named entity recognition (at 1370). Each of these steps may be considered a feature extraction of the document. Historically, extractions have been combined in various ways, which results in an exponential increase in combinations as more features are desired. In response, the present method performs each feature extraction in discrete steps (on an atomic level) and the extractions can be “chained” as desired to extract a specific feature set.

Returning to FIG. 12, after document cleaning, the document is then provided to the transactional assistant for classification using the knowledge sets/base (at 1230). For the purpose of this disclosure, a “knowledge set” is a corpus of domain specific information that may be leveraged by the machine learned classification models. The knowledge sets may include a plurality of concepts and relationships between these concepts. It may also include basic concept-action pairings. The AI Platform will apply large knowledge sets to classify ‘Continue Messaging’, ‘Do Not Email’ and ‘Send Alert’ insights. Additionally, various domain specific ‘micro-insights’ can use smaller concise knowledge sets to search for distinct elements in responses.

The classification may be referred to also as Natural Language Understanding (NLU), which results in the generation of classifications of the natural language and extracted entity information. Rules are used to map the classifications to intents of the language. Classifications and intents are derived via both automated machine learned models as well as through human intervention via annotations. In some embodiments, supervised learning with deep learning or machine learning techniques may be employed to generate the classification models and/or intent rules. Alternatively sentence similarity with TF-IDF (term frequency-inverse document frequency), word embedding similarity, Siamese networks and/or sentence encodings may be leveraged for the intent generation. More rudimentary, but suitable in some cases, pattern or exact matching may be also employed for intent determination. Additionally, external APIs may be leveraged in addition to, or instead of, internally derived methods for intent determination. Entity extraction may be completed using dictionary matches, recurrent neural networks (RNNs) regular expressions, open source third party extractors and/or external APIs. The results of the classification (intent and entity information) are then processed by the inference engine (IE) components of the transactional assistant to determine edge directionality for exchange transitions, and further for natural language generation (NLG) and/or other actions (collectively the action setting steps 1240).

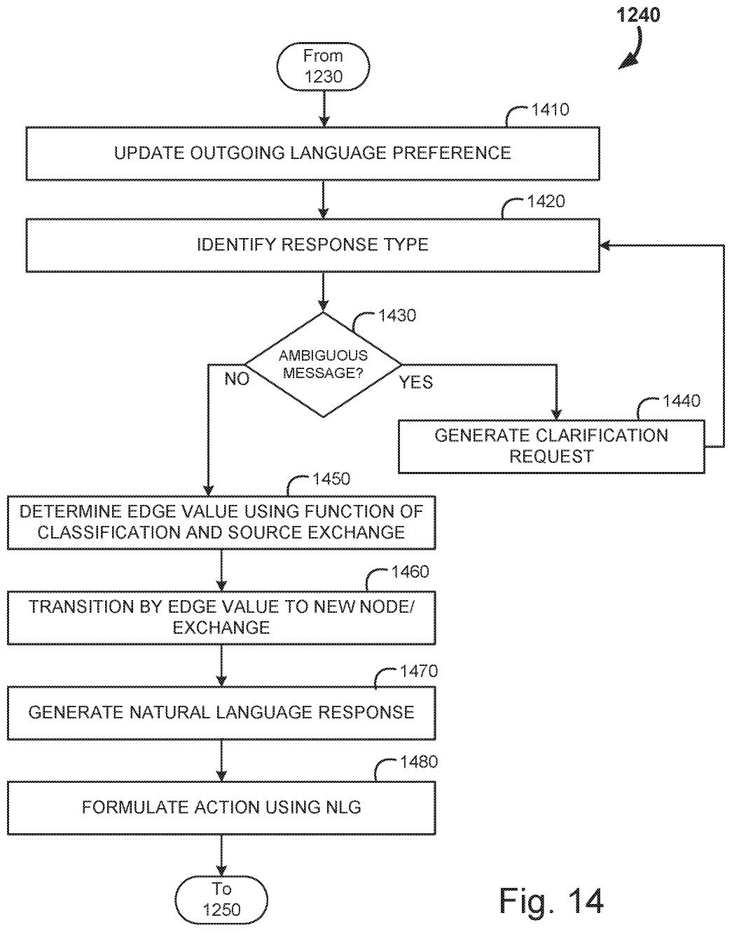

FIG. 14 provides a more detailed view of this action setting step 1240. In this example process, the language utilized in the conversation may be initially checked and updated accordingly (at 1410). As noted previously, language selection may be explicitly requested by the target, or may be inferred from the language used thus far in the conversation. If multiple languages have been used in any appreciable level, the system may likewise request a clarification of preference from the target. Lastly, this process may include responding appropriately if a message language is not supported.

After language preference is determined, the response type is identified (at 1420) based upon the message it is responding to (question, versus informational, vs introductory, etc.). Next a determination is made if the response was ambiguous (at 1430). An ambiguous message is one for which a classification can be rendered at a high level of confidence, but which meaning is still unclear due to lack of contextual cues. Such ambiguous messages may be responded to by generating and sending a clarification request (at 1440) and repeating the analysis.

However, if the message is not ambiguous, then the edge value for the exchange may be determined using a function of the classification and the source exchange (at 1450). As noted before, this function may be any combination of deterministic (such as Boolean rules applied to the intents and entities), machine learning approaches for offline policy learning using historical and audit data, and/or reinforced learning approaches such as multi-armed bandit problem.

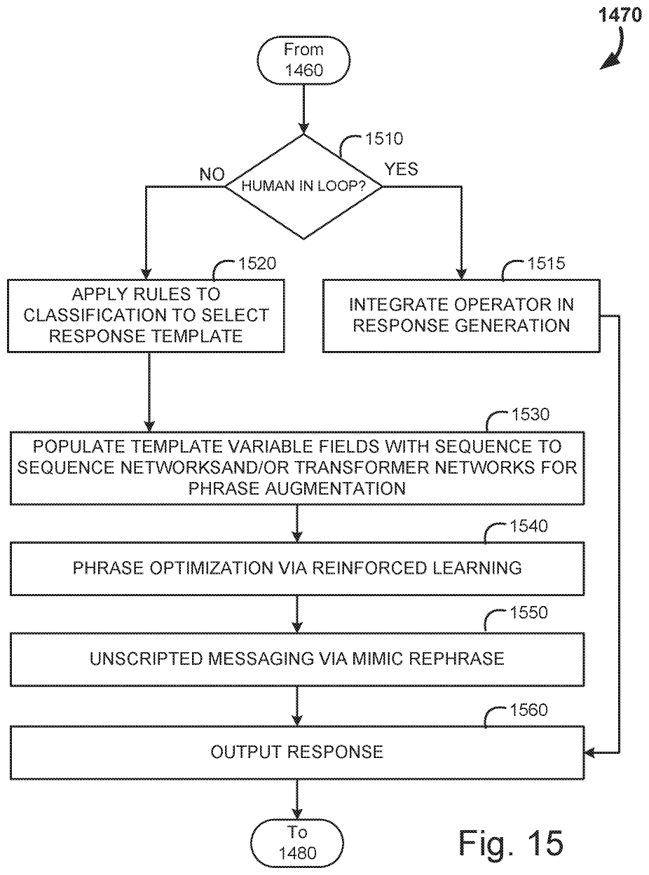

Upon transition to the new exchange state, the transactional assistant can further perform natural language generation (NLG) for the response (at 1470). NLG process is described in greater detail in relation to FIG. 15. NLG may include phrase selection and template population in much the manner already discussed. NLG may likewise include human in the loop (HitL) which integrates with this phrase selection process to curate the outgoing response. Human in the loop is initially determined (at 1510) based upon how confidently the system can generate a viable response. For example, if the target intents are already mapped to a specific set of phrases that have historically been well received and/or approved by a human operator, then there may not be a need for a HitL. However, if the intents are new (or a new combination of intents and entities for the given exchange) then it may be desirable to have human intervention (at 1515).

If the system progresses without human intervention, initially a template is selected related to the classification/intents that were derived from the response (at 1520). Rules linking the intents, entities, and exchange state may be leveraged for template selection. The template is then populated with phrase selections (at 1530). Sequence to sequence networks and transformer networks may be employed to augment the phrases in a dynamically generated message. Additionally or alternatively, reinforced learning algorithms may be employed for phrase selection (at 1540), and unscripted messages may be generated using mimic rephrasing (at 1550). Population of the variable fields includes replacement of facts and entity fields from the conversation library based upon an inheritance hierarchy. The conversation library is curated and includes specific rules for inheritance along organization levels and degree of access. This results in the insertion of customer/industry specific values at specific place in the outgoing messages, as well as employing different lexica or jargon for different industries or clients. Wording and structure may also be influenced by defined conversation objectives and/or specific data or properties of the specific target.

Specific phrases may be selected based upon weighted outcomes (success ranks). The system calculates phrase relevance scores to determine the most relevant phrases given a lead state, sending template, and message component. Some (not all) of the attributes used to describe lead state are: the client, the conversation, the objective (primary versus secondary objective), series in the conversation, and attempt number in the series, insights, target language and target variables. For each message component, the builder filters (potentially thousands of) phrases to obtain a set of maximum-relevance candidates. In some embodiments, within this set of maximum-relevance candidates, a single phrase is randomly selected to satisfy a message component. As feedback is collected, phrase selection is impacted by phrase performance over time, as discussed previously. In some embodiments, every phrase selected for an outgoing message is logged. Sent phrases are aggregated into daily windows by Client, Conversation, Series, and Attempt. When a response is received, phrases in the last outgoing message are tagged as ‘engaged’. When a positive response triggers another outgoing message, the previous sent phrases are tagged as ‘continue’. The following metrics are aggregated into daily windows: total sent, total engaged, total continue, engage ratio, and continue ratio.

In addition to performance-based selection, as discussed above (but not illustrated here), phrase selection may be influenced by the “personality” of the system for the given conversation. Personality of an AI assistant may not just be set, as discussed previously, but may likewise be learned using machine learning techniques that determines what personality traits are desirable to achieve a particular goal, or that generally has more favorable results.

Message phrase packages are constructed to be tone, cadence, and timbre consistent throughout, and are tagged with descriptions of these traits (professional, firm, casual, friendly, etc.), using standard methods from cognitive psychology. Additionally, in some embodiments, each phrase may include a matrix of metadata that quantifies the degree a particular phrase applies to each of the traits. The system will then map these traits to the correct set of descriptions of the phrase packages and enable the correct packages. This will allow customers or consultants to more easily get exactly the right Assistant personality (or conversation personality) for their company, particular target, and conversation. This may then be compared to the identity personality profile, and the phrases which are most similar to the personality may be preferentially chosen, in combination with the phrase performance metrics. A random element may additionally be incorporated in some circumstances to add phrase selection variability and/or continued phrase performance measurement accuracy. Lastly, the generated language may be outputted (at 1560) for use.

Returning to FIG. 14, after NLG, this language may be used, along with other rule based analysis of intents, to formulate the action to be taken by the system (at 1480). Generally, at a minimum, the action includes the ending of the generated message language back to the target, however the action may additionally include other activities such as attaching a file to the message, setting up an appointment using scheduling software, calling a webhook, or the like.

Returning all the way back to FIG. 12, after the actions are generated, a determination is made whether there is an action conflict (at 1250). Manual review may be needed when such a conflict exists (at 1270). Otherwise, the actions may be executed by the system (at 1260).

Returning then to FIG. 10, after the response has been processed, a determination is made whether to deactivate the target (at 1075). Such a deactivation may be determined as needed when the target requests it. If so, then the target is deactivated (at 1090). If not, the process continues by determining if the conversation for the given target is complete (at 1080). The conversation may be completed when all objectives for the target have been met, or when there are no longer messages in the series that are applicable to the given target. Once the conversation is completed, the target may likewise be deactivated (at 1090).

However, if the conversation is not yet complete, the process may return to the delay period (at 1020) before preparing and sending out the next message in the series (at 1030). The process iterates in this manner until the target requests deactivation, or until all objectives are met. This concludes the main process for a comprehensive messaging conversation.

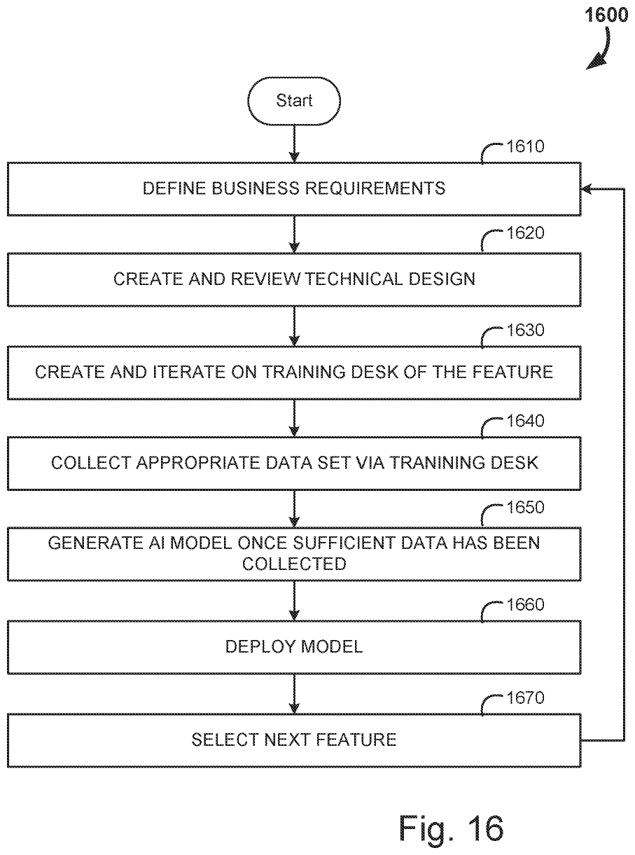

Turning now to FIG. 16, an example process flow diagram is provided for the method of training models of the transactional assistant, shown generally at 1600. This process begins with the definition of the business requirements (at 1610) for a particular model. A new feature requirement should reflect what the leaders of the organization want to accomplish. This defining of the business requirement ensures that the new feature is responsive to these objectives. For example, if for example a frequently asked question with accepted answers (FAQAA) feature is desired, the business requirement may include that customers are interviewed for the generation of the FAQAA but that the FAQAA can be ‘activated’ without the need for offline communications (minimizing business disruption and added effort).

A technical design is created and reviewed (at 1620) for the feature of the model. This may initially be performed by an AI developer, but over time may be machine generated based upon reinforced learning. The technical design is presented to the stakeholders. In the FAQAA example, the technical design may include the capability to annotate general question intents.

After which, the feature can be created within the training desk, and iterated upon (at 1630). The training desk includes human operators that receive the response data and provide annotation input, decisions, and other guidance on the “correct” way to handle the response. Selection of which training desk to create for the feature may depend upon user experience design, user interaction testing, and AB testing to optimize the user interface generated for collecting the feature results from the annotators. This training desk activity can be refined to collect the relevant dataset for the given feature modeling (at 1640). This may include hiring additional annotators for the specific feature being processed, or a self-serve training desk with a core team or early initial adopters. Refinement may also include a temporal element to wait for data collection until quality information is being generated.

Once sufficient data (of sufficient quality) has been accumulated, a machine learned model can then be generated (at 1650) and deployed (at 1660). Generally a few thousand positive and negative labels are required to be collected to generate a model of the desired accuracy. Model data collection and deployment are performed using annotation micro services with continuous model development and self-learning. This training process does not end however, after model deployment the system may select an additional feature (at 1670) and repeat the process for this new feature.

The objective of this feature development activity is that the existence of engineers and computer scientists/developer can be virtually eliminated in such a system over time, and rather all people engaged with the system become users that assist in the system's continued improvement. Essentially, self-improvement is a characteristic of the transactional assistant, thereby ensuring that, over time, fewer and fewer inputs from humans (in the form of annotation events) and developer time (for model construction) occurs. This training methodology is distributed, thereby allowing for faster training process. Additionally, a local mode of operation may be possible to allow for even faster development. Hyperparameter optimization in the distributed and local modes may also be employed to further increase training speed. In some embodiments, the system may include easy extensibility to support other task types as well, such as building word vectors or the like.

Additionally, by allowing each customer to train and deploy their own features, the transactional assistant can be personalized for the given customer. Thus, the operating of the assistant for one company could react very differently than for another company, with all other things being equal. Personalization in such a manner is aided by the ability to readily illustrate to the customer how successful the system is in key metrics. This may include aggregate success metrics, or a deeper dive into specific transactions. By enabling the customer to visualize success of the personalized models they can quickly gain an understanding on the utility offered by the system, the needs of the targets, and can further improve their business operation in response to the conversation results.

### III. System Embodiments

Now that the systems and methods for the conversation generation with improved functionalities have been described, attention shall now be focused upon systems capable of executing the above functions. To facilitate this discussion, FIGS. 17A and 17B illustrate a Computer System 1700, which is suitable for implementing embodiments of the present invention. FIG. 17A shows one possible physical form of the Computer System 1700. Of course, the Computer System 1700 may have many physical forms ranging from a printed circuit board, an integrated circuit, and a small handheld device up to a huge super computer. Computer system 1700 may include a Monitor 1702, a Display 1704, a Housing 1706, a Storage Drive 1708, a Keyboard 1710, and a Mouse 1712. Storage 1714 is a computer-readable medium used to transfer data to and from Computer System 1700.

FIG. 17B is an example of a block diagram for Computer System 1700. Attached to System Bus 1720 are a wide variety of subsystems. Processor(s) 1722 (also referred to as central processing units, or CPUs) are coupled to storage devices, including Memory 1724. Memory 1724 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A Fixed Storage 1726 may also be coupled bi-directionally to the Processor 1722; it provides additional data storage capacity and may also include any of the computer-readable media described below. Fixed Storage 1726 may be used to store programs, data, and the like and is typically a secondary storage medium (such as a hard disk) that is slower than primary storage. It will be appreciated that the information retained within Fixed Storage 1726 may, in appropriate cases, be incorporated in standard fashion as virtual memory in Memory 1724. Removable Storage 1714 may take the form of any of the computer-readable media described below.

Processor 1722 is also coupled to a variety of input/output devices, such as Display 1704, Keyboard 1710, Mouse 1712 and Speakers 1730. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, motion sensors, brain wave readers, or other computers. Processor 1722 optionally may be coupled to another computer or telecommunications network using Network Interface 1740. With such a Network Interface 1740, it is contemplated that the Processor 1722 might receive information from the network or might output information to the network in the course of performing the above-described dynamic messaging processes. Furthermore, method embodiments of the present invention may execute solely upon Processor 1722 or may execute over a network such as the Internet in conjunction with a remote CPU that shares a portion of the processing.

Software is typically stored in the non-volatile memory and/or the drive unit. Indeed, for large programs, it may not even be possible to store the entire program in the memory. Nevertheless, it should be understood that for software to run, if necessary, it is moved to a computer readable location appropriate for processing, and for illustrative purposes, that location is referred to as the memory in this disclosure. Even when software is moved to the memory for execution, the processor will typically make use of hardware registers to store values associated with the software, and local cache that, ideally, serves to speed up execution. As used herein, a software program is assumed to be stored at any known or convenient location (from non-volatile storage to hardware registers) when the software program is referred to as “implemented in a computer-readable medium.” A processor is considered to be “configured to execute a program” when at least one value associated with the program is stored in a register readable by the processor.

In operation, the computer system 1700 can be controlled by operating system software that includes a file management system, such as a storage operating system. One example of operating system software with associated file management system software is the family of operating systems known as Windows® from Microsoft Corporation of Redmond, Wash., and their associated file management systems. Another example of operating system software with its associated file management system software is the Linux operating system and its associated file management system. The file management system is typically stored in the non-volatile memory and/or drive unit and causes the processor to execute the various acts required by the operating system to input and output data and to store data in the memory, including storing files on the non-volatile memory and/or drive unit.

Some portions of the detailed description may be presented in terms of algorithms and symbolic representations of operations on data bits within a computer memory. These algorithmic descriptions and representations are the means used by those skilled in the data processing arts to most effectively convey the substance of their work to others skilled in the art. An algorithm is, here and generally, conceived to be a self-consistent sequence of operations leading to a desired result. The operations are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

The algorithms and displays presented herein are not inherently related to any particular computer or other apparatus. Various general-purpose systems may be used with programs in accordance with the teachings herein, or it may prove convenient to construct more specialized apparatus to perform the methods of some embodiments. The required structure for a variety of these systems will appear from the description below. In addition, the techniques are not described with reference to any particular programming language, and various embodiments may, thus, be implemented using a variety of programming languages.

In alternative embodiments, the machine operates as a standalone device or may be connected (e.g., networked) to other machines. In a networked deployment, the machine may operate in the capacity of a server or a client machine in a client-server network environment or as a peer machine in a peer-to-peer (or distributed) network environment.

The machine may be a server computer, a client computer, a virtual machine, a personal computer (PC), a tablet PC, a laptop computer, a set-top box (STB), a personal digital assistant (PDA), a cellular telephone, an iPhone, a Blackberry, a processor, a telephone, a web appliance, a network router, switch or bridge, or any machine capable of executing a set of instructions (sequential or otherwise) that specify actions to be taken by that machine.

While the machine-readable medium or machine-readable storage medium is shown in an exemplary embodiment to be a single medium, the term “machine-readable medium” and “machine-readable storage medium” should be taken to include a single medium or multiple media (e.g., a centralized or distributed database, and/or associated caches and servers) that store the one or more sets of instructions. The term “machine-readable medium” and “machine-readable storage medium” shall also be taken to include any medium that is capable of storing, encoding or carrying a set of instructions for execution by the machine and that cause the machine to perform any one or more of the methodologies of the presently disclosed technique and innovation.

In general, the routines executed to implement the embodiments of the disclosure may be implemented as part of an operating system or a specific application, component, program, object, module or sequence of instructions referred to as “computer programs.” The computer programs typically comprise one or more instructions set at various times in various memory and storage devices in a computer, and when read and executed by one or more processing units or processors in a computer, cause the computer to perform operations to execute elements involving the various aspects of the disclosure.

Moreover, while embodiments have been described in the context of fully functioning computers and computer systems, those skilled in the art will appreciate that the various embodiments are capable of being distributed as a program product in a variety of forms, and that the disclosure applies equally regardless of the particular type of machine or computer-readable media used to actually effect the distribution

While this invention has been described in terms of several embodiments, there are alterations, modifications, permutations, and substitute equivalents, which fall within the scope of this invention. Although sub-section titles have been provided to aid in the description of the invention, these titles are merely illustrative and are not intended to limit the scope of the present invention. It should also be noted that there are many alternative ways of implementing the methods and apparatuses of the present invention. It is therefore intended that the following appended claims be interpreted as including all such alterations, modifications, permutations, and substitute equivalents as fall within the true spirit and scope of the present invention.

What is claimed is:

1. A method for feature deployment for a transactional assistant comprising:
defining a business requirement for a feature;
creating a technical design for the feature;
generating an optimal training desk responsive to the technical design using user experience design principles and A/B testing;
collecting and aggregating data from the training desk;
generating a model for the feature once the aggregated data is above a minimum threshold;
deploying the model; and
selecting a subsequent feature.

2. A method for conversation customization for a transactional assistant comprising:
collecting human in the loop responses for entities, intents, transaction actions, and replies as a set of annotations;
intelligent querying the set of annotations via an annotation microservice;
automatically building at least one of a natural language understanding (NLU) model, an inference engine (IE) model, and a natural language generation (NLG) model using the queried annotations;
automatically deploying the at least one built model; and
providing alerts responsive to the deployed at least one model.
